(19) United States
(12) Patent Application Publication
(10) Pub. No.: US 2026/0141936 A1
(43) Pub. Date: May 21, 2026

(54) MEMORY PERFORMING COMPUTING OPERATION

(71) Applicant: SK hynix Inc, Gyeonggi-do (KR)

(72) Inventors: Dong Hwan JIN, Gyeonggi-do (KR); Seok Joon KANG, Gyeonggi-do (KR); Jun Ho CHEON, Gyeonggi-do (KR); Sang Hoon JEONG, Gyeonggi-do (KR); Chang Won JEONG, Gyeonggi-do (KR)

(21) Appl. No.: 19/075,788

(22) Filed: Mar. 11, 2025

(30) Foreign Application Priority Data
Nov. 19, 2024 (KR) 10-2024-0164780

(51) Int. Cl. G11C 7/16; G11C 5/14

(52) U.S. Cl. CPC G11C 7/16; G11C 5/147

(57) ABSTRACT

A memory includes a bit line, first to Nth cell groups (N≥2), each with multiple memory cells connected to the bit line, and first to Nth current supply circuits supplying currents to the bit line. The first current supply circuit's current is determined by sensing the bit line current when input voltages are supplied to the first cell group. A kth current supply circuit's current (2≤k≤N) is determined by sensing the bit line current when input voltages are supplied to the first to kth cell groups, with the first to k−1th current supply circuits activated.

### CROSS-REFERENCE TO RELATED APPLICATION

This application claims priority under 35 U.S.C. § 119(a) to Korean Patent Application No. 10-2024-0164780 filed on Nov. 19, 2024, which is incorporated herein by reference in its entirety.

### BACKGROUND

### 1. Technical Field

Embodiments of the present disclosure relate to a memory, and more particularly, to a memory that performs a computing operation.

### 2. Related Art

Electronic devices include many electronic components, and among the electronic devices, a computer system includes many electronic components made of semiconductors. Among the semiconductors constituting the computer system, a host device such as a processor or a memory controller performs data communication with a memory. The memory stores data by including a large number of memory cells arranged in a plurality of rows and a plurality of columns.

Recently, technologies utilizing a memory for a computing operation are being developed in order to improve data processing performance. When the memory directly computes data internally without transmitting the data to a processor, delay due to data movement can be reduced and energy efficiency can be increased.

### SUMMARY

In an embodiment of the present disclosure, a memory may include a bit line; first to N^{th} cell groups, where N is an integer of 2 or more, each cell group including a plurality of memory cells connected to the bit line; and first to N^{th} current supply circuits configured to supply currents to the bit line, wherein a current amount of the first current supply circuit is determined based on a result of sensing the current flowing through the bit line in a state in which input voltages are supplied to the memory cells of the first cell group, and a current amount of a k^{th} current supply circuit, where k is an arbitrary integer ranging from 2 to N, is determined based on a result of sensing the current flowing through the bit line in a state in which input voltages are supplied to the memory cells of the first to k^{th} cell groups and the first to k−1^{th} current supply circuits are activated.

In an embodiment of the present disclosure, an operating method of a memory may include applying first input voltages to memory cells of a first cell group connected to a bit line; generating a first coarse code by performing a coarse analog-to-digital conversion on a current flowing through the bit line by the memory cells of the first cell group; supplying the bit line with a first current corresponding to the first coarse code; applying second input voltages to memory cells of a second cell group connected to the bit line; generating a second coarse code by performing a coarse analog-to-digital conversion on a current flowing through the bit line by the memory cells of the first cell group, the memory cells of the second cell group, and the first current; and supplying the bit line with a second current corresponding to the second coarse code.

In an embodiment of the present disclosure, a memory may include memory cells of a first cell group connected to a bit line; a first current supply circuit configured to supply a current to the bit line to compensate for a current that the memory cells of the first cell group sink from the bit line; memory cells of a second cell group connected to the bit line; and a second current supply circuit configured to supply a current to the bit line to compensate for a current that the memory cells of the second cell group sink from the bit line.

### BRIEF DESCRIPTION OF THE DRAWINGS

FIG. 1 is a mathematical formula showing a multiply-and-accumulate (MAC) computation being the most core computation of deep learning.

FIG. 2 is a diagram illustrating a configuration of a memory in accordance with an embodiment of the present disclosure.

FIG. 3 is a diagram illustrating a configuration of a memory in accordance with another embodiment of the present disclosure.

FIGS. 4A to 4C are diagrams illustrating a process of performing a MAC computation in the memory in FIG. 3.

### DETAILED DESCRIPTION

Various embodiments of the present disclosure are directed to providing a technology for increasing the accuracy of a computing operation of a memory by attenuating an IR drop occurring in a cell array of the memory.

In accordance with embodiments of the present disclosure, the accuracy of a computing operation of a memory can be increased by attenuating an IR drop occurring in a cell array of the memory.

Hereafter, embodiments in accordance with the technical spirit of the present disclosure are described with reference to the accompanying drawings.

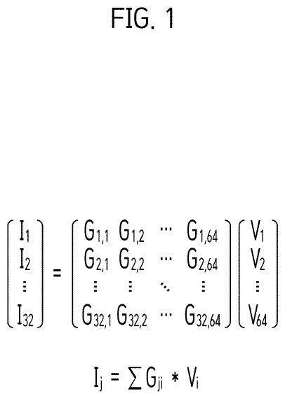

FIG. 1 is a mathematical formula showing a multiply-and-accumulate (MAC) computation being the most core computation of deep learning.

An output I of the MAC computation is defined as the sum of products of weights G and inputs V. In the MAC computation using a memory, because the weight is expressed as the conductance of a memory cell, the symbol of the weight is indicated by G. Because the input is expressed by voltage, the symbol of the input is indicated by V. Because the output is expressed by current, the symbol of the output is indicated by I.

In the following embodiment of the memory, because the size of a cell array is 64×32, the number of inputs V is 64 (V₁ to V₆₄), the number of outputs I is 32 (I₁ to I₃₂), and the number of weights G is 2048 (G_{1,1} to G_{32,64}).

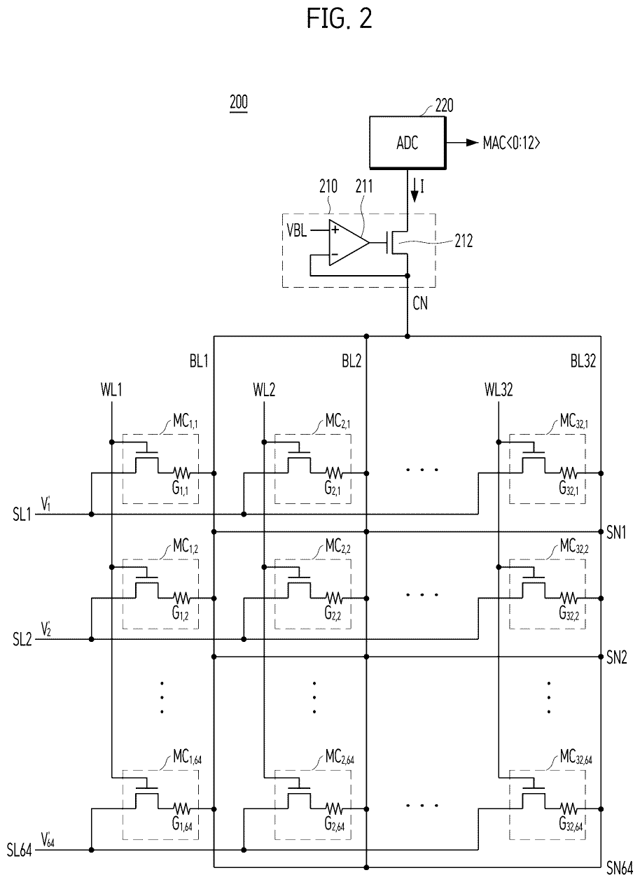

FIG. 2 is a diagram illustrating a configuration of a memory 200 in accordance with an embodiment of the present disclosure.

Referring to FIG. 2, the memory 200 may include word lines WL1 to WL32, bit lines BL1 to BL32, source lines SL1 to SL64, memory cells MC_{1,1} to MC_{32,64}, a voltage regulator 210, and an analog-to-digital converter (ADC) 220.

In an embodiment, the word lines WL1 to WL32 and the bit lines BL1 to BL32 may alternately extend in a first direction. One word line WL and one bit line BL adjacent to each other may form a pair. The source lines SL1 to SL64 may extend in a second direction intersecting the first direction. For example, the second direction may be perpendicular to the first direction. The number of word lines WL1 to WL32, the number of bit lines BL1 to BL32, and the number of source lines SL1 to SL64 illustrated in FIG. 2 are merely examples and may be changed according to an embodiment.

In an embodiment, the memory cells MC_{1,1} to MC_{32,64} may be connected to one of the bit lines BL1 to BL32 and one of the source lines SL1 to SL64. Each of the memory cells MC_{1,1} to MC_{32,64} may be connected to the word line WL having the same number as the bit line BL to which each of the memory cells MC_{1,1} to MC_{32,64} are connected. Among the numbers indicating the memory cells MC_{1,1} to MC_{32,64}, a preceding number corresponds to the number of the bit line BL and the word line WL to which the memory cells are connected, and a following number corresponds to the number of the source line SL to which the memory cells are connected. Each of the memory cells MC_{1,1} to MC_{32,64} may include a variable resistor G having a programmed resistance value and a transistor (e.g., an NMOS transistor). Depending on an embodiment, the memory cell may be implemented with a phase change random access memory (PRAM) cell, a resistance random access memory (RRAM) cell, a magnetic random access memory (MRAM) cell, a ferroelectric random access memory (FRAM) cell, or the like; however, the embodiments are not limited thereto. Depending on an embodiment, the variable resistor may include a phase-change material, perovskite compounds, transition metal oxide, a magnetic material, a ferromagnetic material, or an antiferromagnetic material; however, the embodiments are not limited thereto.

In an embodiment, the voltage regulator 210 may apply a bit line voltage VBL, which is constant, to a common node CN to which the bit lines BL1 to BL32 are connected. The voltage regulator 210 may include an operational amplifier 211 and a transistor 212. Hereinafter, the level of the bit line voltage VBL applied to the bit lines BL1 to BL32 during a computing operation of the memory 200 is illustrated as 0.1 V.

In an embodiment, the ADC 220 may generate a result code MAC<0:12> by performing an analog-to-digital conversion on a current I. The result code MAC<0:12> may be digital codes corresponding to values of Iⱼ in FIG. 1.

In an embodiment, the voltage regulator 210 and the ADC 220 may not be provided for each of the bit lines BL1 to BL32. That is, the voltage regulator 210 and the ADC 220 may be commonly connected to the bit lines BL1 to BL32. Among the bit lines BL1 to BL32, a bit line to be sensed by the ADC 220 may be selected by the word lines WL1 to WL32. When one of the word lines WL1 to WL32 is activated, and a current flowing through the memory cells MC connected to a bit line BL corresponding to the activated word line WL may be converted (sensed) by the ADC 220. For example, when the word line WL2 among the word lines WL1 to WL32 is activated, a current path is formed between the bit line BL2 and the source lines SL1 to SL64 by the memory cells MC_{2,1} to MC_{2,64} which are turned on, and no current path is formed between the bit lines BL1 and BL3 to BL32 and the source lines SL1 to SL64 by the remaining memory cells MC_{1,1} to MC_{1,64} and MC_{3,1} to MC_{32,64} which are turned off.

In an embodiment, the bit lines BL1 to BL32 are shunted at shunt nodes SN1 to SN64. In FIG. 2, while the number of shunt nodes SN1 to SN64 is illustrated as being equal to the number of source lines SL1 to SL64, the shunt nodes SN may be located at regular intervals. For example, one shunt node SN may be allocated to four source lines SL. The shunt nodes SN1 to SN64 may reduce an IR drop by connecting the bit lines BL1 to BL32 in parallel to reduce a resistance in a current path. As described above, a current path between the bit lines BL1 to BL32 and the source lines SL1 to SL64 is formed only through the memory cells of one bit line BL selected by the word line WL, among the bit lines BL1 to BL32. However, because all bit lines BL1 to BL32 are connected in parallel, the line resistance of the bit line BL is reduced. For example, when the word line WL7 is activated and a current path is formed between the bit line BL7 and the source lines SL1 to SL64, because the bit lines BL1 to BL32 are connected in parallel, the resistance of the bit line BL7 may be effectively reduced.

A process of the MAC computation operation being performed in the memory 200 is described below. In the described process, the word line WL1 is activated, the bit line BL1 is selected, and I₁ of FIG. 1 is operated.

In an embodiment, when the word line WL1 is activated, the transistors of the memory cells MC_{1,1} to MC_{1,64} may be turned on. Accordingly, a current path may be formed between the bit line BL1 and the source lines SL1 to SL64 through the memory cells MC_{1,1} to MC_{1,64}. The voltage regulator 210 may apply a bit line voltage VBL of 0.1 V to the bit line BL1.

In an embodiment, input voltages V₁′ to V₆₄′ may be applied to the source lines SL1 to SL64. A current corresponding to G_{1,1}*(0.1−V₁′) may sink from the bit line BL1 to the source line SL1, and a current corresponding to G_{1,2}*(0.1−V₂′) may sink from the bit line BL1 to the source line SL2. That is, a current corresponding to G_{1,i}*(0.1−Vᵢ′) may sink from the bit line BL1 to the source line SLi. Here, G_{1,i} is the conductance of a variable resistance of the memory cell MC_{1,i}, and Vᵢ′ and Vᵢ in FIG. 1 have a relationship of Vᵢ′=0.1−Vᵢ.

As a result, the current corresponding to

$${\sum }_{i = 1} {G}_{1 , i} * {V}_{i}$$

may flow from the bit line BL1 to the source lines SL1 to SL64. The current may be the same as I₁ of FIG. 1. The amount of current flowing from the bit line BL1 to the source lines SL1 to SL64 may be the same as the amount of current flowing to a common node CN, that is, I of FIG. 2. Accordingly, the ADC 220 may perform an analog-to-digital conversion on the current I and generate the result code MAC<0:12> corresponding to the value of I₁ of FIG. 1. It may be expected that, by activating the word lines WL2 to WL32 instead of the word line WL1 to perform the same operation, not only the value of I₁ of FIG. 1 but also the result code MAC<0:12> corresponding to I₂ to I₃₂ are generated.

In an embodiment, to increase the accuracy of the MAC computation, the voltage level of the bit line BL1 needs to be constantly maintained at 0.1 V. However, because a large amount of current, which is the sum of cell currents of 64 memory cells MC_{1,1} to MC_{1,64}, flows through the bit line BL1, even though the resistance value of the bit line BL1 is reduced through the shunt nodes SN1 to SN64, an IR drop due to the resistance of the bit line BL1 may not be avoidable. That is, even though the voltage level of an upper end of the bit line BL1 is maintained at 0.1 V, the voltage level may not be maintained at 0.1 V and gradually decrease toward a lower end of the bit line BL1. Because the voltage level of the bit line BL1 is not maintained at 0.1 V toward the lower end, the cell currents of the memory cells MC_{1,1} to MC_{1,64} may change toward the lower end, and as a result, the MAC computation result becomes inaccurate.

In an embodiment, the phenomenon of the MAC computation result becoming inaccurate due to the IR drop of the bit line BL occurs not only in the bit line BL1, but also in the generation of result code MAC<0:12> corresponding to I₂ to I₃₂ using the other bit lines BL2 to BL32.

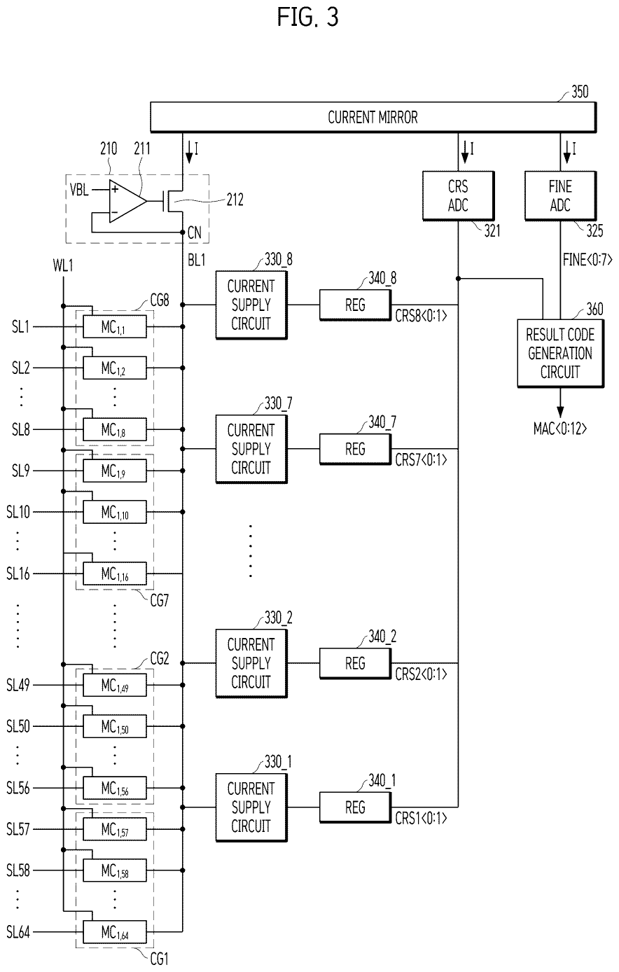

FIG. 3 is a diagram illustrating a configuration of a memory 300 in accordance with another embodiment of the present disclosure.

Referring to FIG. 3, the memory 300 may include a bit line BL1, a word line WL1, source lines SL1 to SL64, memory cells MC_{1,1} to MC_{1,64}, current supply circuits 330_1 to 330_8, registers (REG) 340_1 to 340_8, a voltage regulator 210, a current mirror 350, a coarse analog-to-digital converter (CRS ADC) 321, a fine analog-to-digital converter (FINE ADC) 325, and a result code generation circuit 360.

FIG. 3 merely illustrates one word line WL1, one bit line BL1 and the memory cells MC_{1,1} to MC_{1,64} corresponding to the word line WL1 and the bit line BL1. In addition, a shunt node SN is not illustrated. However, word lines WL, bit lines BL, memory cells MC, and shunt nodes SN may be configured in the same manner as in FIG. 2.

In an embodiment, the memory cells MC_{1,1} to MC_{1,64} may be divided into a plurality of cell groups CG1 to CG8. In FIG. 3, one cell group may be allocated to eight source lines, and the memory cells MC_{1,1} to MC_{1,64} may be divided into first to eighth cell groups CG1 to CG8.

In an embodiment, the current supply circuits 330_1 to 330_8 may compensate for currents that memory cells of a corresponding cell group sink from the bit line BL1. The first current supply circuit 330_1 may supply a current to the bit line BL1 to compensate for currents that memory cells MC_{1,57} to MC_{1,64} of the first cell group CG1 sink from the bit line BL1 to the source lines SL57 to SL64. The second current supply circuit 330_2 may supply a current to the bit line BL1 to compensate for currents that the memory cells MC_{1,49} to MC_{1,56} of the second cell group CG2 sink from the bit line BL1 to the source lines SL49 to SL56. Similarly, the third to eighth current supply circuits 330_3 to 330_8 may supply currents to the bit line BL1 to compensate for currents that the memory cells MC_{1,1} to MC_{1,48} of the third to eighth cell groups CG3 to CG8 sink from the bit line BL1 to the source lines SL1 to SL48.

In an embodiment, the REGs 340_1 to 340_8 may store course codes CRS1<0:1> to CRS8<0:1> for controlling the current amounts of the current supply circuits 330_1 to 330_8, respectively. For example, the current amount of the first current supply circuit 330_1 may be determined by a first course code CRS1<0:1> stored in a first REG 340_1, and the current amount of the fifth current supply circuit 330_5 may be determined by a fifth course code CRS5<0:1> stored in a fifth REG 340_5.

In an embodiment, the voltage regulator 210 may apply a bit line voltage VBL to a common node CN to which the bit line BL1 is connected. The voltage regulator 210 may include an operational amplifier 211 and a transistor 212. The voltage regulator 210 may apply the bit line voltage VBL of 0.1 V to the bit line BL1 during a computing operation.

In an embodiment, the current mirror 350 may mirror a current I flowing through the common node CN, that is, the current flowing through the bit line BL1, and supply the mirrored current to the CRS ADC 321 and the FINE ADC 325.

In an embodiment, the CRS ADC 321 may generate coarse codes CRS1<0:1> to CRS8<0:1> by performing a coarse analog-to-digital conversion on the current I mirrored by the current mirror 350. The coarse codes CRS1<0:1> to CRS8<0:1> may be sequentially generated during the computing operation, and details thereof are described below.

In an embodiment, the FINE ADC 325 may generate a fine code FINE<0:7> by performing a fine analog-to-digital conversion on the current I mirrored by the current mirror 350. The highest bit FINE<7> of the fine code FINE<0:7> may have a binary weight that is half that of the lowest bit CRS<1> of the coarse code CRS<0:1>. Accordingly, the lowest bit CRS<0> of the coarse code CRS<0:1> may have a value 256 times greater than the lowest bit FINE<0> of the fine code FINE<0:7>.

In an embodiment, the result code generation circuit 360 may generate a result code MAC<0:12> by using the coarse codes CRS1<0:1> to CRS8<0:1> and the fine code FINE<0:7>. The result code generation circuit 360 may generate the fine code FINE<0:7> as lower bits MAC<0:7> of the result code MAC<0:12> as is. The result code generation circuit 360 may also generate a value obtained by adding the coarse codes CRS1<0:1> to CRS8<0:1> as upper bits MAC<8:12> of the result code MAC<0:12>.

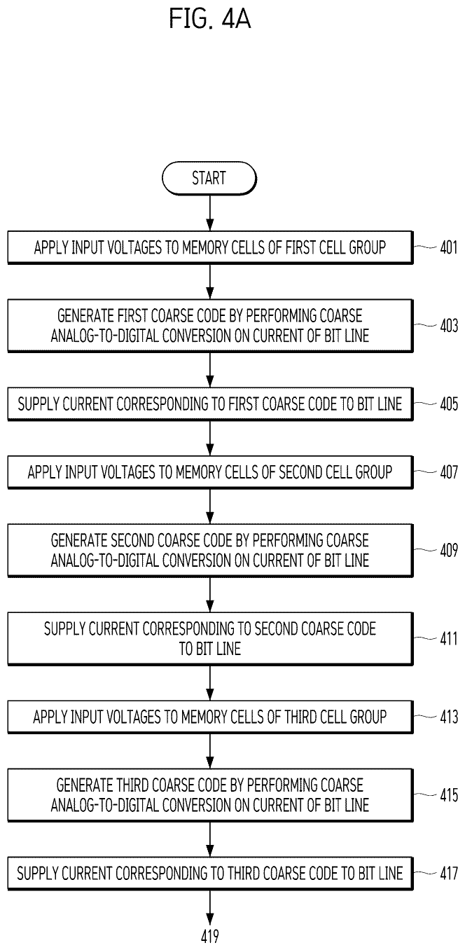

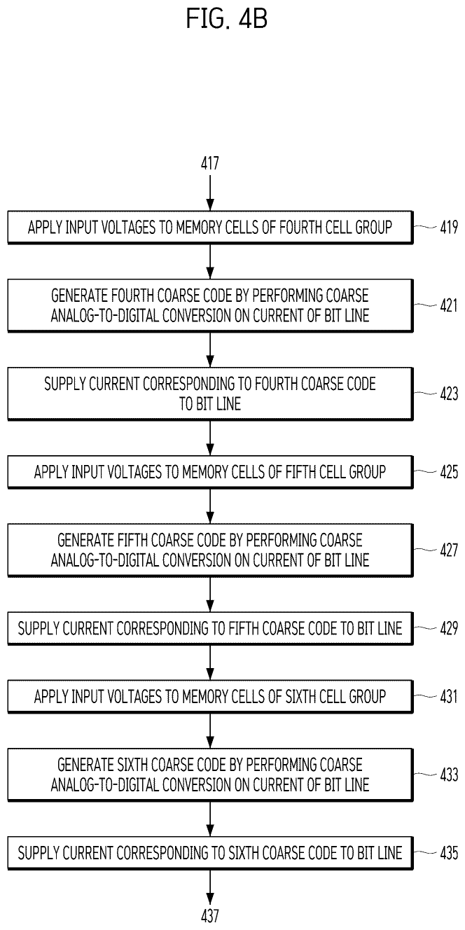

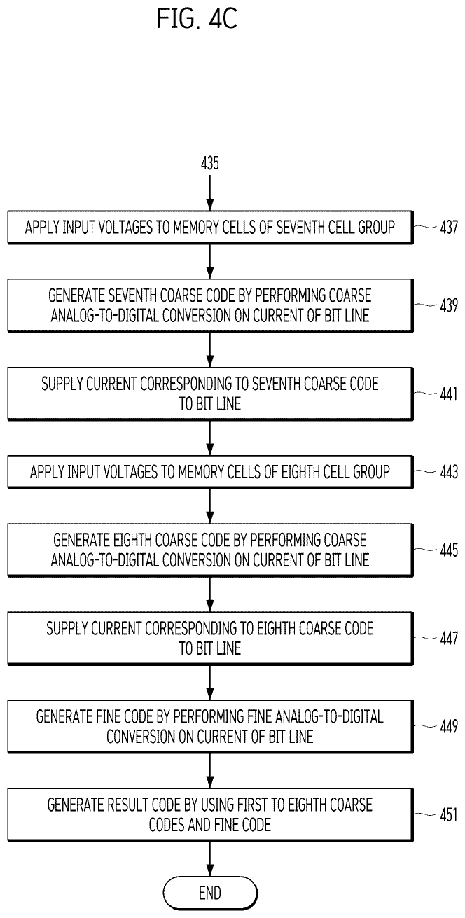

A process of performing the MAC computation in the memory 300 in FIG. 3 is described below with reference to Table 1 and FIGS. 4A to 4C.

Hereinafter, the amount of current that the memory cells MC_{1,57} to MC_{1,64} of the first cell group CG1 sink from the bit line BL1 to the source lines SL57 to SL64 is 23 μA, the amount of current that the memory cells MC_{1,49} to MC_{1,56} of the second cell group CG2 sink from the bit line BL1 to the source lines SL49 to SL56 is 258 μA, the amount of current that the memory cells MC_{1,41} to MC_{1,48} of the third cell group CG3 sink from the bit line BL1 to the source lines SL41 to SL48 is 520 μA, the amount of current that the memory cells MC_{1,33} to MC_{1,40} of the fourth cell group CG4 sink from the bit line BL1 to the source lines SL33 to SL40 is 15 μA, the amount of current that the memory cells MC_{1,25} to MC_{1,32} of the fifth cell group CG5 sink from the bit line BL1 to the source lines SL25 to SL32 is 800 μA, the amount of current that the memory cells MC_{1,17} to MC_{1,24} of the sixth cell group CG6 sink from the bit line BL1 to the source lines SL17 to SL24 is 300 μA, the amount of current that the memory cells MC_{1,9} to MC_{1,16} of the seventh cell group CG7 sink from the bit line BL1 to the source lines SL9 to SL16 is 612 μA, and the amount of current that the memory cells MC_{1,1} to MC_{1,8} of the eighth cell group CG8 sink from the bit line BL1 to the source lines SL1 to SL8 is 90 μA. It is also described that the CRS ADC 321 performs an analog-to-digital conversion on the current I in units of 256 μA and the current amounts of the current supply circuits 330_1 to 330_8 are adjusted to one of 0 μA, 256 μA, 512 μA, and 768 μA. It is also described that the FINE ADC 325 performs an analog-to-digital conversion on the current I in units of 1 μA.

TABLE 1

| | | | | Compensation |
|---|---|---|---|---|
| | | | | (current |
| | Cell group | Bit line | Coarse | supply circuit) |
| | current | current | code | current |
| First cell | 23 | 23 | 00 | 0 |
| group | | | | |
| Second cell | 258 | 281 | 01 | 256 |
| group | | | | |
| Third cell | 520 | 545 | 10 | 512 |
| group | | | | |
| Fourth cell | 15 | 48 | 00 | 0 |
| group | | | | |
| Fifth cell | 800 | 815 | 11 | 768 |
| group | | | | |
| Sixth cell | 300 | 347 | 01 | 256 |
| group | | | | |
| Seventh ell | 612 | 703 | 10 | 512 |
| group | | | | |
| Eighth cell | 90 | 190 | 00 | 0 |
| group | | | | |

### (1) Generation of First Coarse Code CRS1<0:1>

In an embodiment, input voltages V₅₇′ to V₆₄′ may be applied to the memory cells MC_{1,57} to MC_{1,64} of the first cell group CG1 through the source lines SL57 to SL64 (operation 401). In such a case, 0.1 V, which is the same voltage as the bit line BL1, may be applied to the source lines SL1 to SL56 of the memory cells MC_{1,1} to MC_{1,56} of the remaining cell groups CG2 to CG8. That is, no current flows from the bit line BL1 to the source lines SL1 to SL56 through the memory cells MC_{1,1} to MC_{1,56} of the cell groups CG2 to CG8. A current of 23 μA may sink from the bit line BL1 to the source lines SL57 to SL64 through the memory cells MC_{1,57} to MC_{1,64} of the first cell group CG1, and this current becomes the current I of the bit line BL1.

In an embodiment, the CRS ADC 321 may generate the first coarse code CRS1<0:1> by performing a coarse analog-to-digital conversion on the current I of the bit line BL1 mirrored by the current mirror 350 (operation 403). Because the current I of the bit line BL1 is 23 μA and the conversion unit of the CRS ADC 321 is 256 μA, the first coarse code CRS1<0:1> may be generated as ‘00’.

In an embodiment, the first coarse code CRS1<0:1> is stored in the first REG 340_1, and the first current supply circuit 330_1 may supply a current corresponding to the first coarse code CRS1<0:1> to the bit line BL1 (operation 405). Because the first coarse code CRS1<0:1> is ‘00’, the first current supply circuit 330_1 may supply a current of 0 μA to the bit line BL1.

### (2) Generation of Second Coarse Code CRS2<0:1>

Subsequently, input voltages V₄₉′ to V₅₆′ may be applied to the memory cells MC_{1,49} to MC_{1,56} of the second cell group CG2 through the source lines SL49 to SL56 (operation 407). That is, the input voltages V₄₉′ to V₆₄′ may be applied to the source lines SL49 to SL64 of the first cell group CG1 and the second cell group CG2, and 0.1 V, which is the same voltage as the bit line BL1, may be applied to the source lines SL1 to SL48 of the remaining cell groups CG3 to CG8. A current that sinks from the bit line BL1 by the memory cells MC_{1,57} to MC_{1,64} of the first cell group CG1 and the memory cells MC_{1,49} to MC_{1,56} of the second cell groups CG2 and a current supplied by the first current supply circuit 330_1 may flow through the bit line BL1. That is, a current I of 281 μA (=23+258−0) may flow through the bit line BL1.

The CRS ADC 321 may generate the second coarse code CRS2<0:1> by performing a coarse analog-to-digital conversion on the current I of the bit line BL1 mirrored by the current mirror 350 (operation 409). Because the current I of the bit line BL1 is 281 μA and the conversion unit of the CRS ADC 321 is 256 μA, the second coarse code CRS2<0:1> may be generated as ‘01’.

The second coarse code CRS2<0:1> is stored in the second REG 340_2, and the second current supply circuit 330_2 may supply a current corresponding to the second coarse code CRS2<0:1> to the bit line BL1 (operation 411). Because the second coarse code CRS1<0:1> is ‘01’, the second current supply circuit 330_2 may supply a current of 256 μA to the bit line BL1.

### (3) Generation of Third Coarse Code CRS3<0:1>

Subsequently, input voltages V₄₁′ to V₄₈′ may be applied to the memory cells MC_{1,41} to MC_{1,48} of the third cell group CG3 through the source lines SL41 to SL48 (operation 413). That is, the input voltages V₄₁′ to V₆₄′ may be applied to the source lines SL41 to SL64 of the first to third cell groups CG1 to CG3, and 0.1 V, which is the same voltage as the bit line BL1, may be applied to the source lines SL1 to SL40 of the remaining cell groups CG4 to CG8. A current that sinks from the bit line BL1 by the memory cells MC_{1,41} to MC_{1,64} of the first to third cell groups CG1 to CG3 and a current supplied by the first current supply circuit 330_1 and the second current supply circuit 330_2 may flow through the bit line BL1. That is, a current I of 545 μA (=23+258+520−0−256) may flow through the bit line BL1.

The CRS ADC 321 may generate the third coarse code CRS3<0:1> by performing a coarse analog-to-digital conversion on the current I of the bit line BL1 mirrored by the current mirror 350 (operation 415). Because the current I of the bit line BL1 is 545 μA and the conversion unit of the CRS ADC 321 is 256 μA, the third coarse code CRS3<0:1> may be generated as ‘10’.

The third coarse code CRS3<0:1> is stored in the third REG 340_3, and the third current supply circuit 330_3 may supply a current corresponding to the third coarse code CRS3<0:1> to the bit line BL1 (operation 417). Because the third coarse code CRS1<0:1> is ‘10’, the third current supply circuit 330_3 may supply a current of 512 μA to the bit line BL1.

### (4) Generation of Fourth Coarse Code CRS4<0:1>

Subsequently, input voltages V₃₃′ to V₄₀′ may be applied to the memory cells MC_{1,33} to MC_{1,40} of the fourth cell group CG4 through the source lines SL33 to SL40 (operation 419). That is, the input voltages V₃₃′ to V₆₄′ may be applied to the source lines SL33 to SL64 of the first to fourth cell groups CG1 to CG4, and 0.1 V, which is the same voltage as the bit line BL1, may be applied to the source lines SL1 to SL32 of the remaining cell groups CG5 to CG8. A current that sinks from the bit line BL1 by the memory cells MC_{1,33} to MC_{1,64} of the first to fourth cell groups CG1 to CG4 and a current supplied by the first to third current supply circuits 330_1 to 330_3 may flow through the bit line BL1. That is, a current I of 48 μA (=23+258+520+15−0−256−512) may flow through the bit line BL1.

The CRS ADC 321 may generate the fourth coarse code CRS4<0:1> by performing a coarse analog-to-digital conversion on the current I of the bit line BL1 mirrored by the current mirror 350 (operation 421). Because the current I of the bit line BL1 is 48 μA and the conversion unit of the CRS ADC 321 is 256 μA, the fourth coarse code CRS4<0:1> may be generated as ‘00’.

The fourth coarse code CRS4<0:1> is stored in the fourth REG 340_4, and the fourth current supply circuit 330_4 may supply a current corresponding to the fourth coarse code CRS4<0:1> to the bit line BL1 (operation 423). Because the fourth coarse code CRS4<0:1> is ‘00’, the fourth current supply circuit 330_4 may supply a current of 0 μA to the bit line BL1.

### (5) Generation of Fifth Coarse Code CRS5<0:1>

Subsequently, input voltages V₂₅′ to V₃₂′ may be applied to the memory cells MC_{1,25} to MC_{1,32} of the fifth cell group CG5 through the source lines SL25 to SL32 (operation 425). That is, the input voltages V25′ to V₆₄′ may be applied to the source lines SL25 to SL64 of the first to fifth cell groups CG1 to CG5, and 0.1 V, which is the same voltage as the bit line BL1, may be applied to the source lines SL1 to SL24 of the remaining cell groups CG6 to CG8. A current that sinks from the bit line BL1 by the memory cells MC_{1,25} to MC_{1,64} of the first to fifth cell groups CG1 to CG5 and a current supplied by the first to fourth current supply circuits 330_1 to 330_4 may flow through the bit line BL1. That is, a current I of 815 μA (=23+258+520+15+800−0−256−512−0) may flow through the bit line BL1.

The CRS ADC 321 may generate the fifth coarse code CRS5<0:1> by performing a coarse analog-to-digital conversion on the current I of the bit line BL1 mirrored by the current mirror 350 (operation 427). Because the current I of the bit line BL1 is 815 μA and the conversion unit of the CRS ADC 321 is 256 μA, the fifth coarse code CRS5<0:1> may be generated as ‘11’.

The fifth coarse code CRS5<0:1> is stored in the fifth REG 340_5, and the fifth current supply circuit 330_5 may supply a current corresponding to the fifth coarse code CRS5<0:1> to the bit line BL1 (operation 429). Because the fifth coarse code CRS5<0:1> is ‘11’, the fifth current supply circuit 330_5 may supply a current of 768 μA to the bit line BL1.

### (6) Generation of Sixth Coarse Code CRS6<0:1>

Subsequently, input voltages V₁₇′ to V₂₄′ may be applied to the memory cells MC_{1,17} to MC_{1,24} of the sixth cell group CG6 through the source lines SL17 to SL24 (operation 431). That is, the input voltages V₁₇′ to V₆₄′ may be applied to the source lines SL17 to SL64 of the first to sixth cell groups CG1 to CG6, and 0.1 V, which is the same voltage as the bit line BL1, may be applied to the source lines SL1 to SL16 of the remaining cell groups CG7 to CG8. A current that sinks from the bit line BL1 by the memory cells MC_{1,17} to MC_{1,64} of the first to sixth cell groups CG1 to CG6 and a current supplied by the first to fifth current supply circuits 330_1 to 330_5 may flow through the bit line BL1. That is, a current I of 347 μA (=23+258+520+15+800+300−0−256−512−0−768) may flow through the bit line BL1.

The CRS ADC 321 may generate the sixth coarse code CRS6<0:1> by performing a coarse analog-to-digital conversion on the current I of the bit line BL1 mirrored by the current mirror 350 (operation 433). Because the current I of the bit line BL1 is 347 μA and the conversion unit of the CRS ADC 321 is 256 μA, the sixth coarse code CRS6<0:1> may be generated as ‘01’.

The sixth coarse code CRS6<0:1> is stored in the sixth REG 340_6, and the sixth current supply circuit 330_6 may supply a current corresponding to the sixth coarse code CRS6<0:1> to the bit line BL1 (operation 435). Because the sixth coarse code CRS6<0:1> is ‘01’, the sixth current supply circuit 330_6 may supply a current of 256 μA to the bit line BL1.

### (7) Generation of Seventh Coarse Code CRS7<0:1>

Subsequently, input voltages V₉′ to V₁₆′ may be applied to the memory cells MC_{1,9} to MC_{1,16} of the seventh cell group CG7 through the source lines SL9 to SL16 (operation 437). That is, the input voltages V₉′ to V₆₄′ may be applied to the source lines SL9 to SL64 of the first to seventh cell groups CG1 to CG7, and 0.1 V, which is the same voltage as the bit line BL1, may be applied to the source lines SL1 to SL8 of the eighth cell group CG8. A current that sinks from the bit line BL1 by the memory cells MC_{1,9} to MC_{1,64} of the first to seventh cell groups CG1 to CG7 and a current supplied by the first to sixth current supply circuits 330_1 to 330_6 may flow through the bit line BL1. That is, a current I of 703 μA (=23+258+520+15+800+300+612−0−256−512−0−768−256) may flow through the bit line BL1.

The CRS ADC 321 may generate the seventh coarse code CRS7<0:1> by performing a coarse analog-to-digital conversion on the current I of the bit line BL1 mirrored by the current mirror 350 (operation 439). Because the current I of the bit line BL1 is 703 μA and the conversion unit of the CRS ADC 321 is 256 μA, the seventh coarse code CRS7<0:1> may be generated as ‘10’.

The seventh coarse code CRS7<0:1> is stored in the seventh REG 340_7, and the seventh current supply circuit 330_7 may supply a current corresponding to the seventh coarse code CRS7<0:1> to the bit line BL1 (operation 441). Because the seventh coarse code CRS7<0:1> is ‘10’, the seventh current supply circuit 330_7 may supply a current of 512 μA to the bit line BL1.

### (8) Generation of Eighth Coarse Code CRS8<0:1>

Subsequently, input voltages V₁′ to V₈′ may be applied to the memory cells MC_{1,1} to MC_{1,8} of the eighth cell group CG8 through the source lines SL1 to SL8 (operation 443). That is, the input voltages V₁′ to V₆₄′ may be applied to the source lines SL1 to SL64 of the first to eighth cell groups CG1 to CG8. A current that sinks from the bit line BL1 by the memory cells MC_{1,1} to MC_{1,64} of the first to eighth cell groups CG1 to CG8 and a current supplied by the first to seventh current supply circuits 330_1 to 330_7 may flow through the bit line BL1. That is, a current I of 190 μA (=23+258+520+15+800+300+612+90−0−256−512−0−768−256−512) may flow through the bit line BL1.

The CRS ADC 321 may generate the eighth coarse code CRS8<0:1> by performing a coarse analog-to-digital conversion on the current I of the bit line BL1 mirrored by the current mirror 350 (operation 445). Because the current I of the bit line BL1 is 190 μA and the conversion unit of the CRS ADC 321 is 256 μA, the eighth coarse code CRS8<0:1> may be generated as ‘00’.

The eighth coarse code CRS8<0:1> is stored in the eighth REG 340_8, and the eighth current supply circuit 330_8 may supply a current corresponding to the eighth coarse code CRS8<0:1> to the bit line BL1 (operation 447). Because the eighth coarse code CRS8<0:1> is ‘00’, the eighth current supply circuit 330_8 may supply a current of 0 μA to the bit line BL1.

### (9) Generation of Fine Code FINE<0:7> and Generation of Result Code MAC<0:12>

Subsequently, a current that sinks from the bit line BL1 by the memory cells MC_{1,1} to MC_{1,64} of the first to eighth cell groups CG1 to CG8 and a current supplied by the first to eighth current supply circuits 330_1 to 330_8 may flow through the bit line BL1. That is, a current I of 190 μA (=23+258+520+15+800+300+612+90−0−256−512−0−768−256−512−0) may flow through the bit line BL1.

The FINE ADC 325 may generate the fine code FINE<0:7> by performing a fine analog-to-digital conversion on the current I of the bit line BL1 mirrored by the current mirror 350 (operation 449). Because the current I of the bit line BL1 is 190 μA and the conversion unit of the FINE ADC 325 is 1 μA, the fine code FINE<0:7> may be generated as ‘10111110’.

The result code generation circuit 360 generates the result code MAC<0:12> by using the first to eighth coarse codes CRS1<0:1> to CRS8<0:1> and the fine code FINE<0:7> (operation 451). The fine code FINE<0:7> may be generated as the lower bits MAC<0:7> of the result code MAC<0:12> as is. Accordingly, the lower bits MAC<0:7> of the result code MAC<0:12> may be ‘10111110’. The upper bits MAC<8:12> of the result code MAC<0:12> may be generated by adding all of the first to eighth coarse codes CRS1<0:1> to CRS8<0:1>. Accordingly, the upper bits MAC<8:12> of the result code MAC<0:12> may be generated as ‘01001’. As a result, the result code MAC<0:12> may be generated as ‘0100110111110’, and this value may correspond to the value of I₁ of FIG. 1.

According to the MAC computation processes of (1) to (9) described above, a current that the memory cells MC_{1,1} to MC_{1,64} of the cell groups CG1 to CG8 sink from the bit line BL1 can be compensated by a current supplied by the current supply circuits 330_1 to 330_8, while the computing operation is performed. Accordingly, the current I of the bit line BL1 does not increase significantly. Because the current flowing through the bit line BL1 does not increase significantly, the IR drop hardly occurs in the bit line BL1, and as a result, the voltage level of the bit line BL1 can be constantly maintained at a 0.1 V during the computing operation. That is, the MAC computation operation can be performed accurately.

Although the process of calculating I₁ of FIG. 1 by using the memory cells MC_{1,1} to MC_{1,64} connected to the bit lines BL1 has been described, it may be expected that I₂ to I₃₂ of FIG. 1 may be calculated using the memory cells MC_{2,1} to MC_{32,64} connected to the components 330_1 to 330_8, 340_1 to 340_8, 210, 350, 321, 325, and 360 through the bit lines BL2 to BL32.

Although embodiments according to the technical idea of the present disclosure have been described above with reference to the accompanying drawings, this is only for describing the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical concepts of the present disclosure defined in the following claims, and it should be construed that these substitutions, modifications, and changes belong to the scope of the present disclosure. Furthermore, the embodiments may be combined to form additional embodiments.

What is claimed is:

1. A memory comprising:
a bit line;
first to N^{th} cell groups, each cell group comprising a plurality of memory cells connected to the bit line, where N is an integer of 2 or more; and
first to N^{th} current supply circuits configured to supply currents to the bit line,
wherein a current amount of the first current supply circuit is determined based on a result of sensing the current flowing through the bit line in a state in which input voltages are supplied to the memory cells of the first cell group, and
a current amount of a k^{th} current supply circuit is determined based on a result of sensing the current flowing through the bit line in a state in which input voltages are supplied to the memory cells of the first to k^{th} cell groups and the first to k−1^{th} current supply circuits are activated, where k is an arbitrary integer ranging from 2 to N.

2. The memory of claim 1, further comprising:
a voltage regulator configured to apply a constant voltage to the bit line;
a current mirror configured to mirror the current flowing through the bit line; and
a coarse analog-to-digital converter configured to perform an analog-to-digital conversion on the current mirrored by the current mirror, and generate first to N^{th} coarse codes for controlling the first to N^{th} current supply circuits.

3. The memory of claim 2, further comprising:
a fine analog-to-digital converter configured to generate a fine code by performing an analog-to-digital conversion on the current mirrored by the current mirror in a state in which input voltages are supplied to the memory cells of the first to N^{th} cell groups and the first to N^{th} current supply circuits are activated; and
a result code generation circuit configured to generate a result code based on the first to N^{th} coarse codes and the fine code.

4. The memory of claim 3, wherein the result code generation circuit is configured to generate upper bits of the result code by adding the first to N^{th} coarse codes, and generate the fine code as lower bits of the result code.

5. The memory of claim 1, further comprising:
a plurality of source lines connected to the memory cells of the first to N^{th} cell groups, and configured to input the input voltages.

6. The memory of claim 1, wherein each of the plurality of memory cells has a variable resistor.

7. The memory of claim 6, wherein each of the plurality of memory cells further comprises a transistor for controlling an electrical connection of a source line corresponding to the variable resistor in response to a voltage level of a word line.

8. An operating method of a memory, the operating method comprising:
applying first input voltages to memory cells of a first cell group connected to a bit line;
generating a first coarse code by performing a coarse analog-to-digital conversion on a current flowing through the bit line by the memory cells of the first cell group;
supplying the bit line with a first current corresponding to the first coarse code;
applying second input voltages to memory cells of a second cell group connected to the bit line;
generating a second coarse code by performing a coarse analog-to-digital conversion on a current flowing through the bit line by the memory cells of the first cell group, the memory cells of the second cell group, and the first current; and
supplying the bit line with a second current corresponding to the second coarse code.

9. The operating method of claim 8, further comprising:
applying input voltages to memory cells of a k^{th} cell group connected to the bit line;
generating a k^{th} coarse code by performing a coarse analog-to-digital conversion on the current flowing through the bit line by the memory cells of the first to k^{th} cell groups and first to k−1^{th} currents; and
supplying the bit line with a k^{th} current corresponding to the k^{t}h coarse code,
wherein the applying of the input voltages to the memory cells of the k^{th} cell group, the generating of the k^{th} coarse code, and the supplying of the k^{th} current to the bit line are repeated by increasing a value of k ranging from 3 to N, where N is an integer more than 3.

10. The operating method of claim 9, further comprising:
generating a fine code by performing a fine analog-to-digital conversion on the current flowing through the bit line by the memory cells of the first to N^{th} cell groups and the first to N^{th} currents.

11. The operating method of claim 10, further comprising:
generating upper bits of a result code by adding the first to N^{th} coarse codes; and
generating the fine code as lower bits of the result code.

12. The operating method of claim 9, wherein each of the memory cells of the first to N^{th} cell groups sinks a current from the bit line, the current being determined by an input voltage input to each of the memory cells and a programmed resistance value of each of the memory cells.

13. A memory comprising:
memory cells of a first cell group connected to a bit line;
a first current supply circuit configured to supply a first current to the bit line to compensate for a current that the memory cells of the first cell group sink from the bit line;
memory cells of a second cell group connected to the bit line; and
a second current supply circuit configured to supply a second current to the bit line to compensate for a current that the memory cells of the second cell group sink from the bit line.

14. The memory of claim 13, further comprising:
memory cells of third to N^{th} groups connected to the bit line, where N is an integer more than 3; and
third to N^{th} current supply circuits configured to supply third to N^{th} currents to the bit line to compensate for currents that the memory cells of the third to N^{th} groups sink from the bit line.

15. The memory of claim 14, further comprising:
a voltage regulator configured to apply a constant voltage to the bit line;
a current mirror configured to mirror the current flowing through the bit line;
a coarse analog-to-digital converter configured to perform a coarse analog-to-digital conversion on the current mirrored by the current mirror; and
a fine analog-to-digital converter configured to perform a fine analog-to-digital conversion on the current mirrored by the current mirror.

16. The memory of claim 15, wherein a current amount of a k^{th} current supply circuit is controlled by a k^{th} coarse code, where k is an arbitrary integer ranging from 2 to N, and
the k^{th} coarse code is generated by the coarse analog-to-digital converter in a state in which the memory cells of the first to k^{th} groups are activated and the first to k−1^{th} current supply circuits are activated, where all current supply circuits are deactivated when k is 1.

17. The memory of claim 16, further comprising:
a result code generation circuit configured to generate a result code based on the first to N^{th} coarse codes and a fine code generated by the fine analog-to-digital converter.

18. The memory of claim 17, wherein the result code generation circuit is configured to generate upper bits of the result code by adding the first to N^{th} coarse codes, and generate the fine code as lower bits of the result code.
